(19) United States
(12) Patent Application Publication
(10) Pub. No.: US 2012/0090662 A1
(43) Pub. Date: Apr. 19, 2012

(54) THREE-DIMENSIONAL PHOTOVOLTAIC GENERATOR

(75) Inventors: Philippe Edouard Gravisse, Paris (FR); Marc Schiffmann, Masserac (FR)

(73) Assignee: Laboratoire De Physique Du Rayonnement Et De La Lumiere, Paris (FR)

(21) Appl. No.: 13/201,159

(22) PCT Filed: Feb. 12, 2010
(86) PCT No.: PCT/EP10/51807

§ 371 Date: Dec. 7, 2011

(30) Foreign Application Priority Data
Feb. 12, 2009 (FR) 0900635

(51) Int. Cl. H01L 31/055

(52) U.S. Cl. 136/247

(57) ABSTRACT

The present disclosure relates to a photovoltaic generator, including at least one block with transparent walls and at least one reflecting wall, as well as photovoltaic cells, wherein the walls opposite the reflecting wall are transparent and include optically active dopants that transform incident solar radiation into radiation, the spectrum of which is shifted towards the range of the photovoltaic cells with the highest sensitivity, and at least one transparent wall is covered with a dichroic filter.

### CROSS-REFERENCE TO RELATED APPLICATIONS

This application is a National Phase Entry of International Application No. PCT/EP2010/051807, filed on Feb. 12, 2010, which claims priority to French Patent Application Serial No. 0900635, filed on Dec. 12, 2009, both of which are incorporated by reference herein.

### BACKGROUND AND SUMMARY

The invention concerns a three-dimensional (3D) photovoltaic generator, notably for a photovoltaic tower with high photovoltaic output.

U.S. Pat. No. 3,912,931 is known in the state of the art, describing a radiant energy amplifying device. This patent describes an incident solar energy transfer by shifting the wavelength to the range of greatest sensitivity of the photocell by optically active dopants (optically active molecules) constituting a stack of specially doped layers, the emission of one corresponding to the absorption of the other.

U.S. Pat. No. 4,088,508 describes an improvement in which the energy transfer is carried out by a homogeneous doped matrix making possible a better electromagnetic conversion output. French Patent No. 7,808,150 describes a homogeneous mixed matrix consisting of OAC (optically active crystals) of “rare earth” type and forming a cascade of light emitting in the near IR the greatest sensitivity of a silicon photocell.

U.S. Pat. No. 4,324,946 describes different architectures of flat and/or cylindro-parabolic collectors capable of trapping the photons in a plate with cascades of light and bringing them by waveguide to the photocells placed on the section of cascades of light. A factor N electric gain is thus obtained with equal silicon surface. The cascade of light doped matrix is transparent in the visible, consisting perhaps of a window.

French Patent No. 9,212,713 in the name of applicant describes an electromagnetic energy concentrator with frequency change constituting, among other things, an electromagnetic diode, applicable notably to photovoltaic devices of single or multiple “flat collector” type with optical concentration effect. The concept of cascades of light associated with dichroism is described here for the first time in the literature. U.S. Pat. No. 6,570,083 B2 describes photovoltaic generators with cascade of light and variation of electromagnetic flux, specifically describing 2D and 3D generators with active encapsulation by collection and frequency shift of incident photons by simple and inverse cascades of light (STOKES and anti-STOKES).

U.S. Pat. No. 4,367,367 is also known in the state of the art, describing a photovoltaic generator comprising at least one block having transparent walls. This block consists of a transparent top surface and lateral walls provided with photovoltaic cells and at least one reflecting surface. The walls opposite the reflecting wall and the photovoltaic cells are transparent and contain optically active dopants transforming the incident radiation into a radiation adapted to the photoconversion spectrum.

The photovoltaic generator according to the invention makes it possible to improve the output of such photovoltaic generators, notably when the insolation conditions are optimal.

The invention concerns, according to a first aspect, a photovoltaic generator comprising at least one rectangular parallepipedal block or module, having transparent walls and at least one reflecting wall, as well as photovoltaic cells, characterized in that the walls opposite the reflecting wall are transparent and contain optically active dopants transforming the incident solar radiation into a radiation whose spectrum is shifted toward the range of greater sensitivity of the photovoltaic cells, and in that at least one wall is covered with a dichroic filter. The photovoltaic generator advantageously comprises a juxtaposition of blocks, the photovoltaic cells of each block being arranged in parallel planes.

According to a variant, the said parallel planes containing the photovoltaic cells are oriented in relation to the transparent faces so as to maximize the surface oriented in the direction of insolation in midday on the installation site of the generator. The planes of the photovoltaic cells preferably form an angle ranging between 30° and 60° relative to the axis of illumination. According to a variant, the generator further contains an aerogenerator placed at the top of a juxtaposition of blocks. According to a second aspect, the invention concerns a photovoltaic farm comprising a plurality of photovoltaic generators according to the invention, distributed to minimize the solar masking.

### BRIEF DESCRIPTION OF THE FIGURES

Other advantages and characteristics of the invention will appear on reading the description, illustrated by the figures representing:

FIG. 1, a 3D view of an example of a photovoltaic generator according to the invention;

FIG. 2, a 3D view of another example of a photovoltaic generator according to the invention;

FIG. 3, a diagram illustrating the principle of cascades of light;

FIGS. 4A to 4B, views of an example of a generator according to the invention, integrating an aerogenerator; and

FIG. 5, a diagram of an example of a generator according to the invention, integrated in a natural environment.

### DETAILED DESCRIPTION

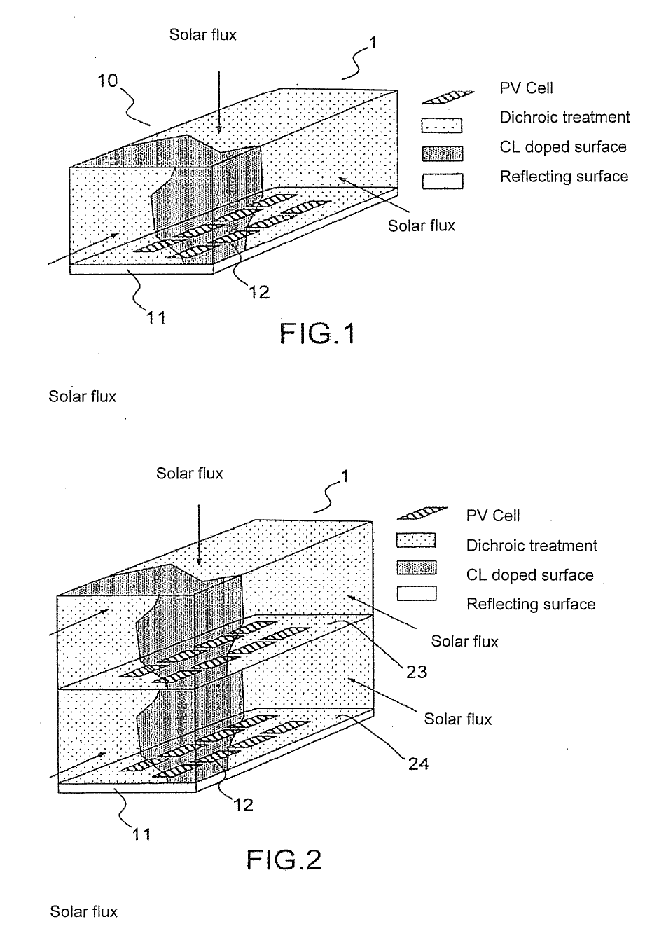

FIG. 1 illustrates an embodiment of a photovoltaic generator 1 with a block 10 or module. The module has a reflecting wall 11 and photovoltaic cells 12. In this example, the block is formed by a rectangular parallelepiped, the photovoltaic dells (of known type) being arranged in a plane parallel to the reflecting wall 11. The other walls of the module, perpendicular to the plane of the photovoltaic cells facing it, are transparent in the visible and coated in this example with a material forming a cascade of light, making it possible to transform the incident solar radiation into a radiation whose spectrum is shifted toward the range of greater sensitivity of the photovoltaic cells, and of a low-pass dichroic coating.

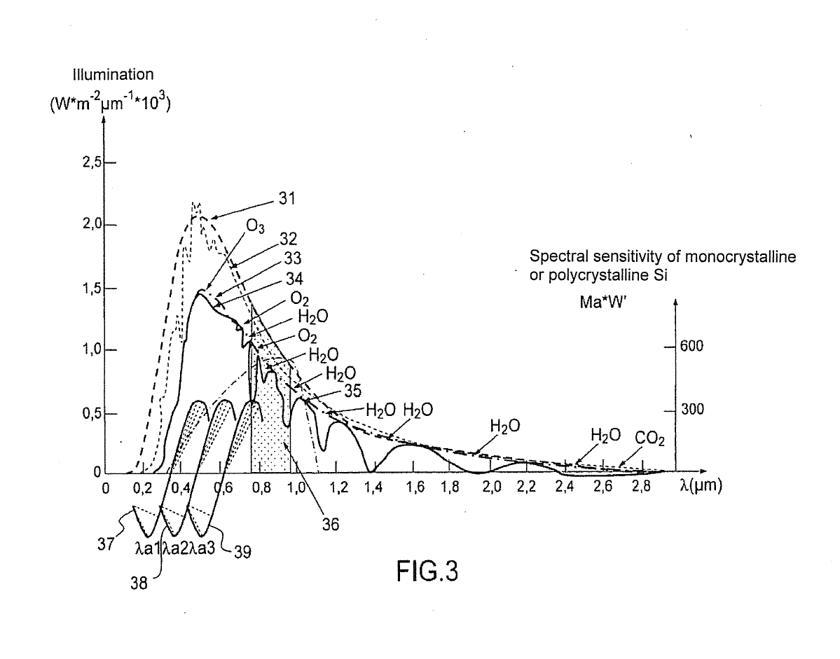

The principle of the cascades of light is explained in FIG. 3. Curve 31 represents the energy curve of the black body at 6000 K, curve 32 illustrates the solar radiation outside the atmosphere (AM0), curve 33 illustrates the solar radiation at sea level (AM1), curve 34 illustrates the solar radiation at sea level taking into account the absorption due to water vapor as well as the presence of certain gases (AM1, 5), curve 35 illustrates the spectral response of a monocrystalline or polycrystalline photovoltaic silicon (Si) cell and the zone 36 of the range of maximum spectral sensitivity of the monocrystalline or polycrystalline Si photocell. Curves 37 to 39 illustrate the absorption and emission curves of three photoluminescent charges of absorption peaks λₐ1, λₐ2, λₐ3, respectively and of emission peaks λₑ1, λₑ2, λₑ3, respectively, in which emission of the first corresponds to absorption of the second, emission of the second corresponding to absorption of the third, whence the term cascade of light, making it possible to mobilize in the wavelength range of greater sensitivity of the solar cells to silicon, for example, the maximum electromagnetic energy by frequency shift of the incident solar spectrum.

In fact, the maximum energy emission peaks of the sun at AM1 or AM0 are situated at 365 and 450 nm in the UV and the blue, while the maximum sensitivity peak of the Si photocells (N+P), for example, is situated toward 900 nm. Between 365 and 440 nm, the photocells have a conversion power of only 25 and 50% of their maximum potential. The incident photons in these solar bands of greater energy are, therefore, transformed for a large part of them into heat, thus heating the cells and proportionally reducing their output. The interest that can be initially drawn from transfer of the photons of higher frequency (wavelength λᵢ between 365 and 440 nm) into low frequency (wavelength λₑ between 800 and 900 nm) is therefore evident.

According to an embodiment, a PMMA—polymethyl methacrylate—type matrix is made and is then doped with optically active dopants, optically active molecules of aromatic cyclic type, for example, the number of cores φ of which determine the absorption and emission wavelengths.

It is also possible to apply on the transparent walls the material forming a cascade of light in the form of a projectable varnish or glass spray, for example. According to an example, the cascades of light, as used in the generator of the invention, absorb the light in the 300 to 700 nanometer range and re-emit at a wavelength of approximately 950 nanometers. Their effect is conjugated with that of the dichroic coatings, acting as a low-pass filter, making it to possible to cut off radiations above 950 nm, for example.

The modules of the type described in FIG. 1 are advantageously juxtaposable, as is illustrated in FIG. 2, for example, in order to form large-sized structures, such as photovoltaic conversion towers. The generator 1 of FIG. 2 comprises a juxtaposition of two modules 20 and 21. In that example, the photovoltaic cells of each block are arranged in parallel planes, noted 23 and 24, respectively. In the example of FIG. 2, the walls intended to receive sunlight are transparent, covered with a material forming a cascade of light and with a low-pass dichroic coating, making it possible to cut off radiations above 950 nm, for example. According to a variant, not represented in FIG. 2, the parallel planes containing the photovoltaic cells can be oriented relative to the transparent faces so as to maximize the surface oriented in the direction of insolation in midday on the installation site of the generator.

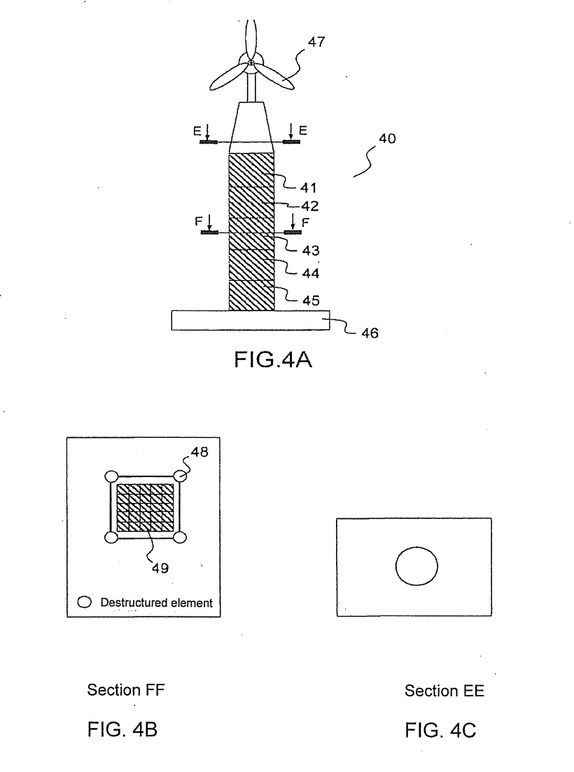

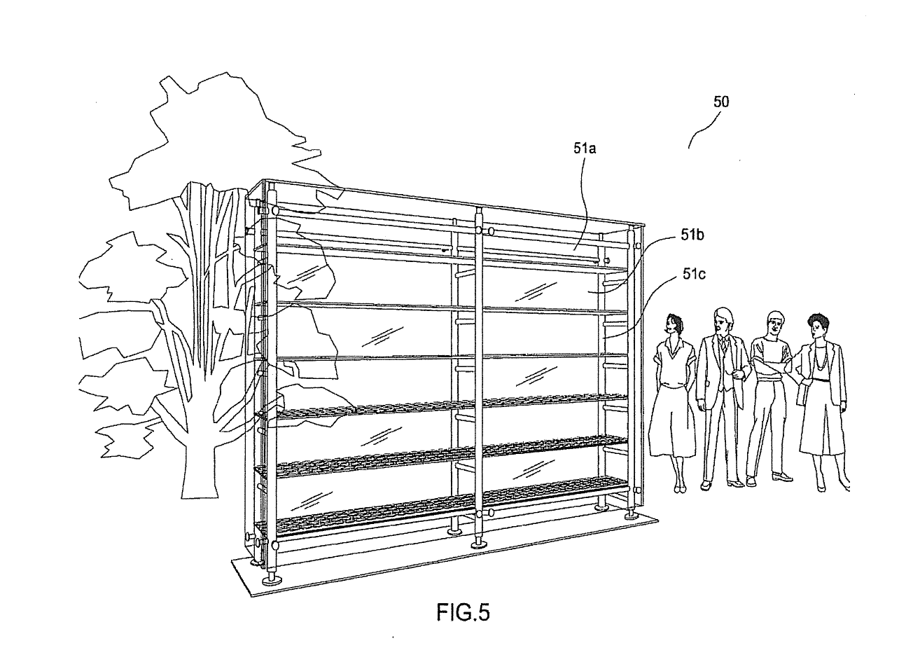

FIGS. 4 and 5 illustrate two examples of photovoltaic generators or towers formed by juxtaposition of modules, such as described, for example, with respect to FIGS. 1 and 2. The generator 40 of FIG. 4A comprises a juxtaposition of modules 41 to 46, of the type described in FIG. 1, for example, arranged on a base 46 and forming a pylon structure. The generator 40 also includes an aeraulic system 47 making it possible to form an aerogenerator. The bottom part of the pylon is, for example, prismatic or square (see section FF of a module represented in FIG. 4B), and the top part is advantageously circular (FIG. 4C) for aerodynamic reasons (to avoid turbulent patterns in proximity to the aerogenerator). Section FF (FIG. 4B) shows the structural elements 48 of the pylon and the photovoltaic cells 49.

The invention thus enables photovoltaic towers to be made, one example of which is represented in FIG. 5. The tower 50 of FIG. 5 comprises a juxtaposition of modules 51a to 51f of the FIG. 1 type, for example. The towers are advantageously spread out on the ground to minimize the effects of luminous masking. The free spaces between the towers facilitate maintenance and accessibility of equipment and can also be earmarked for other uses.

One advantage of a photovoltaic tower according to the invention is, notably, to obtain a soil occupancy coefficient (SOC) higher than 2, the surface of the photovoltaic cells being at least twice as great as that of the space required by the tower on the ground. Furthermore, thanks to the surface of the walls covered with a material forming a cascade of light and dichroic coating, perpendicular to the surface of the photovoltaic cells, the photon collection surface can be increased in relation to the surface of the photovoltaic cells, thus making it possible either to reduce the cell packing factor or to increase the quantity of photoelectric energy produced on an equal silicon surface.

Though described through a number of detailed embodiments, the rack with double glazing according to the invention embraces different variants, modifications and improvements which will appear evident to one skilled in the art, it being understood that these different variants, modifications and improvements form part of the scope of the invention, as defined in the following claims.

1. A photovoltaic generator comprising at least one rectangular parallepipedal module, the module having a plurality of transparent walls and at least one reflecting wall and a photovoltaic cell, at least one of the walls containing optically active dopants configured to transform an incident solar radiation into a radiation whose spectrum is shifted toward a range of greater sensitivity of the photovoltaic cells, and in that at least one wall is covered with a dichroic filter.

2. The photovoltaic generator according to claim 1, further comprising a juxtaposition of blocks, the photovoltaic cells of each block being arranged in parallel planes.

3. The photovoltaic generator according to claim 2, wherein the parallel planes containing the photovoltaic cells are oriented in relation to the plurality of transparent faces so as to maximize the surface oriented in the direction of insolation in midday on the installation site of the generator.

4. The photovoltaic generator according to claim 3, wherein the planes of the photovoltaic cells form an angle ranging between 30° and 60° relative to the axis of illumination.

5. The photovoltaic generator according to claim 2, further comprising an aerogenerator placed at the top of the juxtaposition of blocks.

6. A photovoltaic generator comprising:
a reflective surface;
a first photovoltaic cell having a predefined spectral response curve between preferred first and second electromagnetic frequencies; and
a generally transparent wall having a first optically active dopant, the first dopant configured to absorb an electromagnetic wave at a first portion of the electromagnetic spectrum and emit an electromagnetic wave at a second portion of the electromagnetic spectrum, the second portion of the electromagnetic spectrum being between the first and second electromagnetic frequencies;
wherein the photovoltaic cell is positioned to receive light from the transparent window and reflected by the reflective layer.

7. The photoelectric generator according to claim 6, wherein the transparent layer further comprises a second optically active dopant, the second optically active dopant absorbs light from the second portion of the electromagnetic spectrum and emits radiation at a third portion of the electromagnetic spectrum, wherein a portion of the third portion of the electromagnetic spectrum falls between the first and second electromagnetic frequencies.

8. The photoelectric generator according to claim 6, further comprising a second photovoltaic cell positioned generally parallel to the first photovoltaic cell.

9. The photovoltaic generator according to claim 6, further comprising a second photovoltaic cell positioned generally perpendicular to the first photovoltaic cell.

10. The photovoltaic generator according to claim 9, wherein the first and second photovoltaic cells are generally perpendicular to the transparent wall.

11. The photovoltaic generator according to claim 6, wherein the transparent wall comprises a low pass dichroic coating.

12. The photovoltaic generator according to claim 6, wherein the first photovoltaic cell is optically positioned between the transparent wall and the reflective surface.

13. The photovoltaic generator according to claim 6, wherein the first photovoltaic cell is coplanar with the second photovoltaic cell and is optically positioned between the transparent wall and the reflective surface.

14. A photovoltaic generator having a plurality of modules, each module comprising:
a plurality of photovoltaic cells having a preferred spectral response range between a first and a second frequency;
a transparent wall comprising a first active dopant which transforms an incident solar radiation into a radiation whose spectrum is shifted toward the preferred spectral range; and
a reflective wall, wherein one of the transparent wall or the reflective walls comprise a dichroic filter.

15. The photovoltaic generator according to claim 14, further comprising a plurality of modules.

16. The photovoltaic generator according to claim 14, wherein the transparent wall comprises a second active dopant which transforms electromagnetic radiation from at least one of radiation transmitted by the first dopant or incident radiation, and emit radiation at a frequency within the preferred spectral response range.

17. The photovoltaic generator according to claim 14, wherein the reflector comprises a dichroic filter.

18. The photovoltaic generator according to claim 14, wherein the plurality of photovoltaic cells are perpendicular to the transparent wall.

19. The photovoltaic cell according to claim 14, further comprising a third photovoltaic cell positioned generally parallel to the transparent wall.

20. The photovoltaic generator according to claim 14, further comprising a second transparent wall, the transparent wall comprising a third dopant which transforms incident solar radiation into radiation having a frequency spectrum shifted toward the preferred spectral response range.
